(19) United States
(12) Patent Application Publication
(10) Pub. No.: US 2005/0035663 A1
(43) Pub. Date: Feb. 17, 2005

(54) Electromagnetic pulse generator

(76) Inventors: Steven Moore, Escondido, CA (US); John Santhoff, San Diego, CA (US)

Correspondence Address: PULSE-LINK, INC., 1969 KELLOGG AVENUE, CARLSBAD, CA, 92008, US

(21) Appl. No.: 10/633,606

(22) Filed: Jul. 31, 2003

(51) Int. Cl. H03K 3/00

(52) U.S. Cl. 307/106

(57) ABSTRACT

A system, method and apparatus for an electromagnetic pulse generator is provided. In one embodiment of the present invention, a computer software interface provides control signals to an array of electromagnetic pulse generation gates. Electromagnetic pulses generated by the array of electromagnetic pulse generation gates may be aggregated to form a desired waveform. One feature of the invention is that the electromagnetic waveforms generated are compatible with a number of different communications methods and technologies. This Abstract is provided for the sole purpose of complying with the Abstract requirement rules that allow a reader to quickly ascertain the subject matter of the disclosure contained herein. This Abstract is submitted with the explicit understanding that it will not be used to interpret or to limit the scope or the meaning of the claims.

### Field Of The Invention

The present invention relates to electromagnetic pulse generation. More specifically, it relates to circuits, systems and methods of electromagnetic pulse generation.

### BACKGROUND OF THE INVENTION

The wireless device industry has recently seen unprecedented growth. With the growth of this industry, communication between wireless devices has become increasingly important. There are a number of different technologies for inter-device communications. Radio frequency (RF) technology has been the predominant technology for wireless device communications. Electro-optical devices have also been used in wireless communications. However, electro-optical technology suffers from low ranges and a strict need for line of sight. RF devices therefore provide significant advantages over electro-optical devices.

Conventional RF technology employs continuous sine waves that are transmitted with data embedded in the modulation of the sine waves' amplitude or frequency. For example, a conventional cellular phone must operate at a particular frequency band of a particular width in the total frequency spectrum. Specifically, in the United States, the Federal Communications Commission has allocated cellular phone communications in the 800 to 900 MHz band. Generally, cellular phone operators divide the allocated band into 25 MHz portions, with selected portions transmitting cellular phone signals, and other portions receiving cellular phone signals.

Another type of inter-device communication technology is ultra-wideband (UWB). UWB wireless technology is fundamentally different from conventional forms of RF technology. UWB employs a “carrier free” architecture, which generally does not require the use of high frequency carrier generation hardware; carrier modulation hardware; frequency and phase discrimination hardware or other devices employed in conventional frequency domain (i.e., RF) communication systems.

A number of architectures for use of ultra-wideband communications have been suggested. In one approach, the frequency spectrum allocated to UWB communications devices is partitioned into discrete bands. Modulation techniques and wireless channelization schemes can then be designed around a UWB device operating within one or more of these sub-bands. Alternatively, a UWB communications device may occupy all or substantially all of the entire allocated spectrum.

Regardless of the amount of spectrum employed, most UWB communication devices may then use a modulation technique. For example, a UWB device may generate UWB pulses at specific amplitudes and or phases. All of these approaches require a UWB device to generate specific types of pulses, or pulse morphology, to conform to the desired architecture, or modulation technique.

Therefore, there exists a need for an electromagnetic pulse generator that can generate electromagnetic pulses of a desired duration.

### SUMMARY OF THE INVENTION

The present invention provides circuits, systems, methods and apparatus for an electromagnetic pulse generator. A preferred embodiment of the present invention comprises a software controllable electromagnetic pulse generator. In one embodiment of the present invention, a computer software interface provides control signals to an array of electromagnetic pulse generation gates. The gates are activated by a transition of a control signal from one voltage level to another voltage level. During the transition time an electromagnetic pulse is formed in the output of each gate.

An alternative embodiment of the present invention may aggregate the discrete electromagnetic pulses into a desired waveform.

One feature of the invention is that the electromagnetic waveforms generated are compatible with a number of different communications methods and technologies.

These and other features and advantages of the present invention will be appreciated from review of the following detailed description of the invention, along with the accompanying figures in which like reference numerals refer to like parts throughout.

### BRIEF DESCRIPTION OF THE DRAWING

FIG. 1 is an illustration of different communication methods;

FIG. 2 is an illustration of two ultra-wideband pulses;

FIG. 3 shows a schematic diagram of a programmable pulse generator constructed according to one embodiment of the present invention;

FIG. 4 shows a schematic diagram of a programmable pulse generator employing a demultiplexer constructed according to another embodiment of the present invention;

FIG. 5 shows a schematic diagram of two series-connected arrays of pulse generation cells constructed according to one embodiment of the present invention;

FIG. 6 shows a schematic diagram of a two parallel-connected arrays of pulse generation cells constructed according to another embodiment of the present invention;

FIG. 7 shows a schematic diagram of a parallel-connected cell arrays with an arithmetic combining circuit constructed according to one embodiment of the present invention;

FIG. 8 shows one aggregate output of the pulse generation cells and/or arrays of the present invention arranged to form a electromagnetic waveform;

FIG. 9 shows different electromagnetic pulses employed in a multi-band ultra-wideband communication system;

FIG. 10 shows the frequency space occupied by the electromagnetic pulses in FIG. 9; and

FIG. 11 shows different electromagnetic pulses formed by the electromagnetic pulses generation cells and/or arrays of the present invention.

It will be recognized that some or all of the Figures are schematic representations for purposes of illustration and do not necessarily depict the actual relative sizes or locations of the elements shown.

### DETAILED DESCRIPTION OF THE INVENTION

In the following paragraphs, the present invention will be described in detail by way of example with reference to the attached drawings. Throughout this description, the preferred embodiment and examples shown should be considered as exemplars, rather than as limitations on the present invention. As used herein, the “present invention” refers to any one of the embodiments of the invention described herein, and any equivalents. Furthermore, reference to various feature(s) of the “present invention” throughout this document does not mean that all claimed embodiments or methods must include the referenced feature(s).

There are many useful applications for extremely short duration pulses of electromagnetic energy. For example, in RADAR and other imaging applications short electromagnetic pulse durations can improve the resolution capability of the system. In ultra-wideband communications extremely short duration pulses are desirable as well. The present invention provides an apparatus, method and system for electromagnetic pulse generation having extremely short duration.

In one embodiment of the present invention, a number of extremely short duration pulse generation cells are aggregated into an array. The aggregation may involve serial aggregation of control inputs, serial aggregation of pulse generation cell outputs, as well as parallel aggregation of both control inputs and pulse generation cell outputs. The data inputs, control inputs, and the on/off state of the current sources may be under digital computer software control through the use of a microprocessor or a finite state machine.

Conventional radio frequency technology employs continuous sine waves that are transmitted with data embedded in the modulation of the sine waves' amplitude or frequency. For example, a conventional cellular phone must operate at a particular frequency band of a particular width in the total frequency spectrum. Specifically, in the United States, the Federal Communications Commission has allocated cellular phone communications in the 800 to 900 MHz band. Cellular phone operators use 25 MHz of the allocated band to transmit cellular phone signals, and another 25 MHz of the allocated band to receive cellular phone signals.

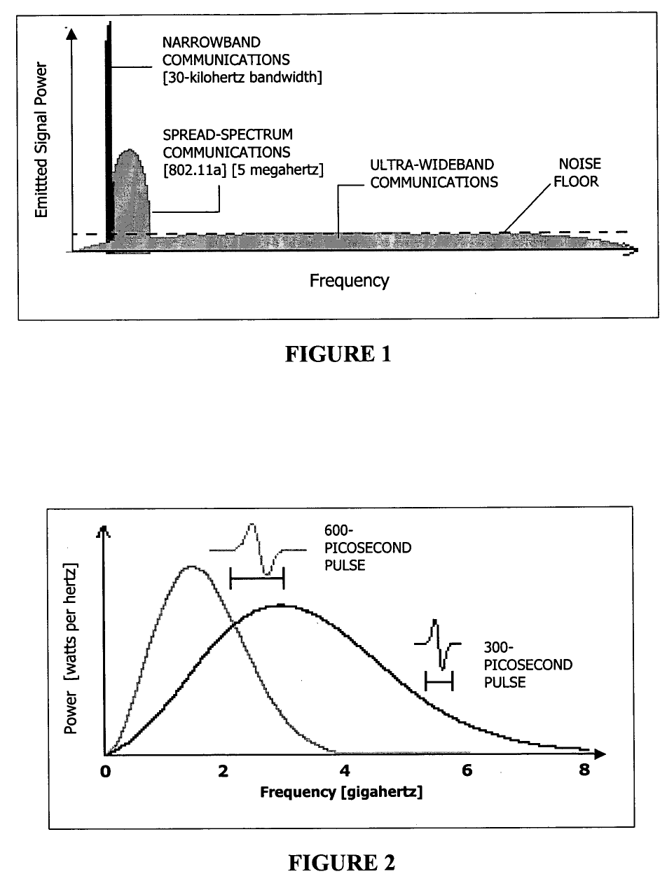

Another example of a conventional radio frequency technology is illustrated in FIG. 1. 802.11a, a wireless local area network (LAN) protocol, transmits radio frequency signals at a 5 GHz center frequency, with a radio frequency spread of about 5 MHz.

In contrast to conventional “carrier wave” communications, another type of communication technology is emerging. Known as ultra-wideband (UWB), or impulse radio, it employs pulses of electromagnetic energy that are emitted at nanosecond or picosecond intervals (generally tens of picoseconds to a few .nanoseconds in duration). For this reason, ultra-wideband is often called “impulse radio.” Because the excitation pulse is not a modulated waveform, UWB has also been termed “carrier-free” in that no apparent carrier frequency is evident in the radio frequency (RF) spectrum. That is, the UWB pulses are transmitted without modulation onto a sine wave, or carrier frequency, in contrast with conventional radio frequency technology. Ultra-wideband requires neither an assigned frequency, a power amplifier, high frequency carrier generation hardware, carrier modulation hardware, stabilizers, frequency and phase discrimination hardware or other devices employed in conventional frequency domain communication systems.

Referring to FIG. 2, two ultra-wideband pulses are illustrated. As shown, an ultra-wideband (UWB) pulse may have a 1.8 GHz center frequency, with a frequency spread of approximately 3.2 GHz, which illustrates two typical UWB pulses. FIG. 2 illustrates that the narrower the UWB pulse in time, the broader the spread of its frequency spectrum. This is because frequency is inversely proportional to the time duration of the pulse. A 600-picosecond UWB pulse can have about a 1.8 GHz center frequency, with a frequency spread of approximately 1.6 GHz. And a 300-picosecond UWB pulse can have about a 3 GHz center frequency, with a frequency spread of approximately 3.2 GHz. And, a 50-picosecond UWB pulse can have about a 10 GHz center frequency, with a frequency spread of approximately 20 GHz. As mentioned above, the present invention is capable of producing extremely short duration electromagnetic pulses. For example, the present invention may produce electromagnetic pulses having a duration of as little as 5 picoseconds.

Thus, UWB pulses generally do not operate within a specific frequency, as shown in FIG. 1. And because UWB pulses are spread across an extremely wide frequency range, UWB communication systems allow communications at very high data rates, such as 100 megabits per second or greater.

Further details of UWB technology are disclosed in U.S. Pat. No. 3,728,632 (in the name of Gerald F. Ross, and titled: Transmission and Reception System for Generating and Receiving Base-Band Duration Pulse Signals without Distortion for Short Base-Band Pulse Communication System), which is referred to and incorporated herein in its entirety by this reference.

Also, because the UWB pulse is spread across an extremely wide frequency range, the power sampled at a single, or specific frequency is very low. For example, a UWB one-watt signal of one nano-second duration spreads the one-watt over the entire frequency occupied by the pulse. At any single frequency, such as a cellular phone carrier frequency, the UWB pulse power present is one nano-watt (for a frequency band of 1 GHz). This is well within the noise floor of any cellular phone system and therefore does not interfere with the demodulation and recovery of the original cellular phone signals. Generally, the UWB pulses are transmitted at relatively low power (when sampled at a single, or specific frequency), for example, at less than −30 power decibels to −60 power decibels, which minimizes interference with conventional radio frequencies.

As described above, conventional wireless devices communicate with Radio Frequency (RF) energy. Conventional technologies for RF communications employ RF carrier waves. Data is modulated onto the carrier wave, amplified and transmitted from a RF device. A second RF wireless device receives the carrier wave, amplifies the wave, and demodulates the data. RF communications suffer from fading, multi-path interference, and channel attenuation. Since RF energy strength is proportional to the inverse of the transmitted distance squared, the quality of RF wireless communication is dependent on the relative location of the RF devices that are communicating. Atmospheric conditions, terrain, natural and man-made objects can additionally degrade the received signal strength of RF communications

One feature of the present invention is that with extremely short electromagnetic pulse generation capability, software-defined radio becomes feasible. That is, a conventional radio transmitter generally comprises a carrier-wave generator constructed to transmit a specific radio frequency, a device for modulating the carrier wave in accordance with information to be broadcast, amplifiers and an aerial system. This conventional radio transmitter transmits an electromagnetic waveform (the sinusoidal carrier-wave) at a specific frequency.

Software-defined radio is communication in which carrier signals are generated, modulated, and decoded only by computer software. This allows a single computer-controlled receiver, transmitter or transceiver to interface and operate with a variety of communication services that use different frequencies, modulation methods and/or protocols. Changing the frequency, modulation method and/or protocol only requires using a different computer software program. Thus, software-defined radio is much more economical to manufacture, package, and produce.

One feature of the present invention is that a group of short duration pulses of electromagnetic energy can be aggregated, or “stacked-up” to form a conventional radio frequency signal (a sinusoidal waveform). A communication signal sampling theorem states that a signal must be sampled at twice the highest frequency component to be reliably recovered. This signal sampling theorem is generally known as either the Nyquist sampling theorem or the Shannon sampling theorem.

One corollary of this sampling theorem is that electromagnetic pulse generation systems can be used to represent, or simulate, continuous waveform signals if the time resolution, or duration of the pulses is such that the inverse of resolution is at least twice the highest frequency component in the desired waveform. For example, to aggregate a pulsed signal to represent cellular communications at 900 MHz would require at a minimum a 555 pico-second pulse duration. To replicate a 802.11(a) (i.e., BLUETOOTH) waveform would require pulse durations of 100 pico-seconds or less since the center frequency assigned to that communications technology is approximately 5 GHz. Additionally, to represent some conventional signal modulation techniques, the amplitude of the carrier waveform must also be reliably constructed. Therefore, re-creation, or simulation, of an amplitude modulated waveform may require the capability to produce extremely short duration pulses while controlling the amplitude of the pulses.

One capability envisioned by the present invention is a single mobile, or fixed, wireless device that can switch between various wireless, or wire communication technologies and standards. By way of example and not limitation, a device constructed according to the present invention may communicate with BLUETOOTH, WiFi, UWB, CDMA, GSM, PCS and a host of other communication technologies by employing a software-defined radio. One feature of the present invention is the generation and aggregation of extremely short duration electromagnetic pulses into waveforms that simulate a wide range of wireless communication technologies.

Wireless communication technologies may use a number of modulation techniques to impart data to the signal prior to transmission. Most of these modulation techniques are imparted to an existing carrier signal that changes properties based on the data. For example, in phase modulation schemes the phase of a carrier waveform is shifted in increments depending of the data to be imparted. In Amplitude Modulation (AM) the amplitude of the carrier signal is varied by the data to be carried. In Orthogonal Frequency Division Modulation (OFDM) data is modulated onto a set of orthogonal carriers prior to transmission. Since the carriers are selected to be orthogonal, there is minimal interference between the resultant modulated signals.

Ultra-wideband (UWB) pulse modulation techniques enable a single representative data symbol to represent a plurality of binary digits, or bits. This has the obvious advantage of increasing the data rate in a communication system. A few examples of UWB modulation include Pulse Width Modulation (PWM), Pulse Amplitude Modulation (PAM), and Pulse Position Modulation (PPM). In PWM, a series of pre-defined UWB pulse widths are used to represent different sets of bits. For example, in a system employing 8 different UWB pulse widths, each symbol could represent one of 8 combinations. This symbol would carry 3 bits of information. In PAM, pre-defined UWB pulse amplitudes are used to represent different sets of bits. A system employing PAM16 would have 16 pre-defined UWB pulse amplitudes. This system would be able to carry 4 bits of information per symbol. In a PPM system, pre-defined positions within an UWB pulse timeslot are used to carry a set of bits. A system employing PPM16 would be capable of carrying 4 bits of information per symbol. Additional UWB pulse modulation techniques, not listed, may be employed by the present invention.

One feature of the present invention is that it allows a computer software control unit to select appropriate electromagnetic pulse generation cells in such a way as to generate a carrier signal that is already modulated to reflect the desired data to be sent. This can reduce the complexity and expense of communication device design in that modulation hardware is no longer necessary to impart data onto the carrier signal.

An additional feature of the present invention is that it may act as a “bridge” between different communication technologies. By way of example and not limitation, a narrowband PCS signal may be received at a frequency of approximately 1.9 GHz. A communication device employing the present invention may re-transmit the PCS signal by transmitting a 900 MHz signal that conforms with a CDMA communication system. Alternatively, the re-transmission may employ a UWB wireless link using UWB communication methods described above. The UWB wireless link may transmit across a frequency band extending from about 3.1 GHz to about 10.6 GHz.

One embodiment of the present invention provides a computer software controllable waveform generator for use in wireless, or wire communication that aggregates a number of extremely short duration pulses. Further details of extremely short electromagnetic pulse generation techniques and methods are discussed in detail in METHODS, APPARATUSES, AND SYSTEMS FOR SAMPLING OR PULSE GENERATION, U.S. Pat. No. 6,433,720, issued to Libove et al., on Aug. 13, 2002, which is incorporated herein by reference in its entirety.

The electromagnetic pulse generation cell(s) employed in the present invention may have one, or more software controllable interfaces. In one embodiment, the software control interface employs at least one digital to analog conversion (DAC) circuit. In this embodiment, a DAC may be used to provide the control signal of the pulse generation cell(s). Alternatively, a DAC may be used to deactivate a switch placed inline with the current source of each pulse generation cell effectively shutting down unused pulse generation cell(s). Alternatively, a DAC may be used by a software control unit to control the flow of data to the input stage of each pulse generation cell. A still further use of a software controlled DAC would provide control signals to the aggregation or combining circuit that combines the output of serial and/or parallel arrays of pulse generation cells. Additionally a DAC may be used to provide threshold voltage levels in the pulse generation cell(s).

In another embodiment of the present invention, a computer microprocessor or alternatively a finite state machine, may send signals directly to the above mentioned inputs without the use of DAC hardware. A finite state machine is any device that stores the status of something at a given time and can operate on input to change the status and/or cause an action or output to take place for any given change. Thus, at any given moment in time, a computer system can be seen as a set of states and each program in it as a finite state machine. For example, a finite state machine may be a hardware implementation of computer logic, or software.

As conceived herein, electromagnetic pulse generation cells may be configured in a number of ways. In one embodiment, pulse generation cells are connected in series, relative to the control input, with a single set of output terminals to form a Serial Array Single Output (SASO). In this embodiment delay lines may be used to set the time of pulse generation of each cell relative to the first cell's output. Generally, a delay line is a device that introduces a time lag in a signal. The time lag is usually calculated as the time required for the signal to pass though the delay line device, minus the time necessary for the signal to traverse the same distance without the delay line.

In this configuration, a transition in a control signal generates a pulse proportional to the data input on the first cell. The control signal then passes through a delay line to a second cell and causes a pulse to be generated in the output proportional to the data input on the second cell. The second pulse is delayed in time relative to the first by the delay in the control signal. Subsequent stages in the SASO can be further delayed providing pulse outputs at their appropriate time interval. This configuration may be used without delay lines causing the pulses produced by each individual cell to be summed at the output terminals.

Another configuration of pulse generation cells involves connecting in series, relative to the control input, a number of cells where each cell has output terminals. In this configuration, a serial input multiple output (SAMO), can be implemented with or without delay lines to provide simultaneous outputs or outputs that are temporally spaced due to the delay in the control transition. In this configuration, the outputs may be summed at a common node, or provided to a mixing circuit such as a Gilbert Multiplier, or a Half Gilbert Multiplier, and the product of the two signals is then taken.

In a still further configuration, a combination of electromagnetic pulse generation cells may be connected in parallel, relative to the control inputs. In this configuration, each pulse generation cell may receive a different control signal. In this configuration, the timing of the control inputs can directly control generation and temporal spacing of the pulses. The cells may be configured to have a single output (PASO) or multiple outputs (PAMO).

In another configuration, two-dimensional arrays of SASO, SAMO, PASO, and PAMO arrays may be connected serially or in parallel to provide additional functionality.

In conventional communication technologies a carrier waveform is generated then data is modulated onto the waveform. For example, most conventional systems use a local oscillator to provide a sine wave carrier, and then data is modulated onto the carrier, or waveform. In some forms of ultra-wideband communications, a pulse is generated then filtered or mixed to achieve a desired center frequency. In one embodiment of the present invention, the pulse generation cells are configured to produce waveforms at the desired center frequency, and are also configured to represent data in its modulated form. This reduces the complexity and expense of the transmitter design by eliminating modulation and mixing hardware and potentially eliminating the need for bandpass filters.

By controlling the shape of a generated waveform to the tens of picoseconds, it is possible to limit the frequency content of the resultant waveform. One feature of the present invention provides a waveform generator for electronic communication systems that complies with FCC emission limit regulations without employing bandpass filters to reject out-of-band emissions.

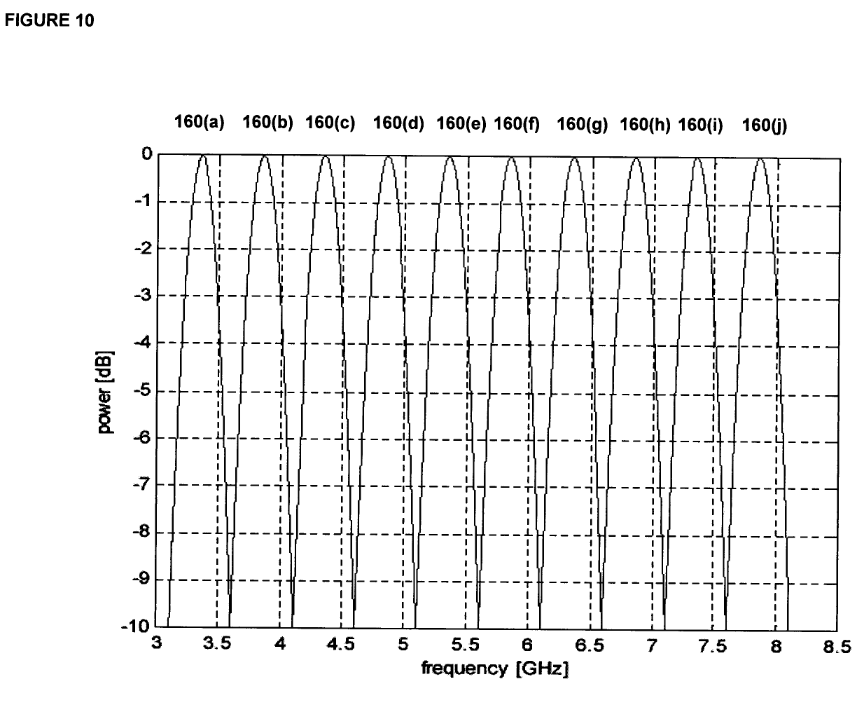

Another feature of the present invention provides an electromagnetic pulse generator that may be software controlled to produce ultra-wideband (UWB) pulses compliant with both single-band and multi-band UWB systems. Current Federal Communications Commission (FCC) regulations establish “spectrum masks” that limit outdoor ultra-wideband emissions to −41 dBm between 3.1 GHz and 10.6 GHz. A single-band ultra-wideband (UWB) communication system may emit UWB pulses having a frequency spread that would extend from about 3.1 GHz to about 10.6 GHz. A multi-band UWB communication system may break-up the available frequency and emit UWB pulses in discrete frequency bands, for example, 200 MHz bands, 400 MHz bands, 600 MHz bands. It will be appreciated that other frequency band allocations may be employed. An example of a possible multi-band UWB communication system is illustrated in FIG. 10.

Additionally, the present invention allows a communication device to bridge, or convert data received from a single-band UWB communication system to a multi-band communication system and vice-versa, as well as bridging data between conventional carrier wave communication technologies as described above, and UWB communication technologies.

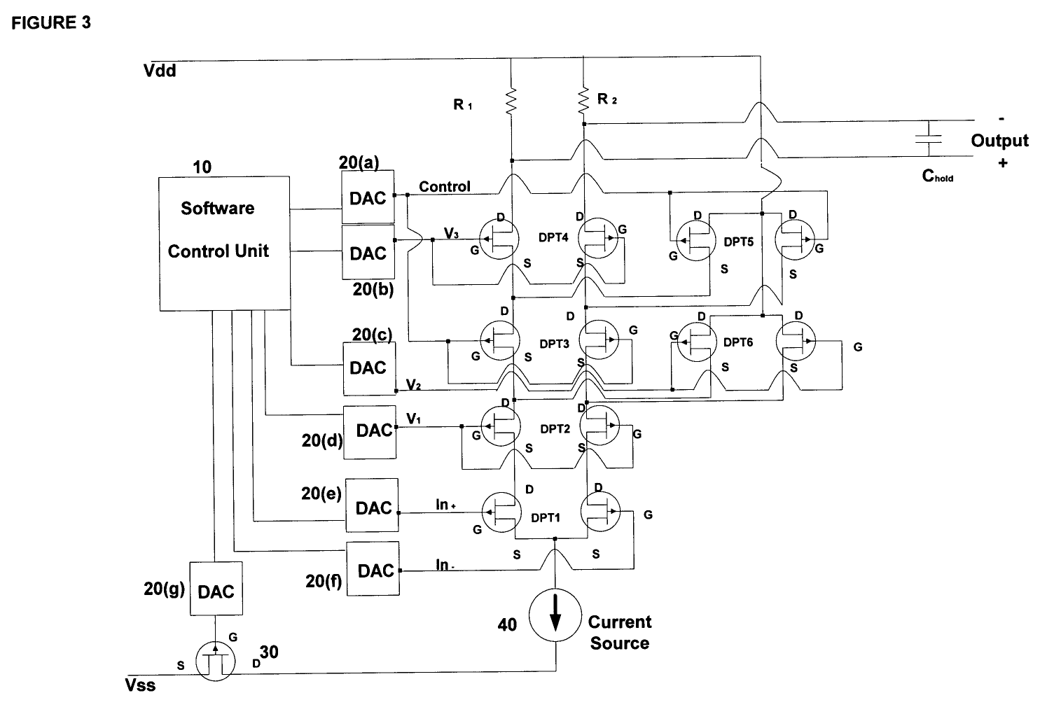

Referring now to FIG. 3, a computer. software controllable electromagnetic pulse generation cell is illustrated. Software Control Unit (SCU) 10 is capable of providing a number of control signals to the cell. SCU may comprise a microprocessor or alternatively may comprise a finite state machine capable of providing the necessary digital control signals to the various parts of the pulse generation cell. The SCU 10 may be coupled to a plurality of optional Digital to Analog Control (DAC) circuits 20(a-g). DAC circuits 20(a-g) may comprise multi-bit DAC circuits or alternatively be replaced by voltage divider circuits configured to provide specific voltage levels used by the pulse generation cell. Switching device 30 is under control of the SCU through optional DAC 20(g). Switching device 30 provides the function of shutting down the current source and subsequently the pulse generation cell. The SCU can provide data signals through optional DACs 20(e) and 20(f) as differential input signals to the gate connections of differential pair transistors (DPT) 1.

Current Source 40 provides current through the pulse generation cell. Current Source 40 may comprise any number of common current source configurations including current mirrors. Additionally, Current Source 40 may be mirrored to other pulse generation cells to provide current to those cells. DPT 1 has source terminals (S) connected to Current Source 40. The activation terminal, or gate terminal (G) accepts data inputs from the SCU 10 through optional DACs 20(e) and 20(f). DPT 1 has drain terminals (D) connected to the source terminals (S) of DPT 2. DPT 2 is an optional DPT that can be used to prevent transient voltages and currents from other DPTs from affecting DPT 1.

In the embodiment not employing DPT 2, the drain terminals (D) of DPT 1 are connected directly to the source terminals (S) of DPT 3. In that embodiment, optional DAC 20(d) or another voltage division circuit (not shown) is not used. DPT 3 has gate terminals (G) connected to a control signal that may be provided by SCU 10 through the optional DAC 20(a). In one embodiment, the drain terminals (D) of DPT 3 are connected to the source terminals (S) of DPT 2. In another embodiment, the drain terminals (D) are connected directly to the source terminals (S) of DPT 1. The drain terminals (D) of DPT 3 are connected to the source terminals (S) of DPT 4.

DPT 4 has gate terminals (G) connected to a voltage level V₃ that may be provided by SCU 10 through DAC 20(b) or optionally through a voltage divider circuit (not shown). The source terminals (S) of DPT 4 are connected to the drain terminals (D) of DPT 3.

The drain terminals (D) of DPT 4 are connected to a pair of resistive circuit elements R, R2. Any number of devices may be used to provide a specific resistance in a circuit, or cell such as transistors having a specific output resistance, usually referred to as an active load.

DPT 5 has gate terminals (G) connected to the control signal that may be provided by SCU 10 through optional DAC 20(a). The drain terminals (D) of DPT 5 are connected to voltage source Vdd. The source terminals (S) of DPT 5 are connected to the source terminals (S) of DPT 4 and therefore the drain terminals (D) of DPT 3. DPT 6 has gate terminals (G) connected to voltage V2 which can be provided by SCU 10 through DAC 20(c) or optionally from a voltage division circuit driven by either the SCU 10 or Vdd. In the latter case, the voltage at this point is not software controllable. Resistive circuit elements R1, R2 are connected to voltage source Vdd on one end and to the drain connections of DPT 4 on the other. A differential output is taken from the connection between resistive circuit elements R1, R2 and the drain terminals (D) of DPT 4. An optional energy storage element Chold may be included in the circuit to provide the output signals for a specific hold time.

The operation of the circuit in FIG. 3 is dependent on a number of voltage levels: Control, V1, V2, V3, Vdd, and Vss. The primary function of voltage level V1 is to ensure that optional DPT 2 is in the “on” state. The active pulse generation time period occurs when one, or more of DPTs are in transition from one fixed state to another fixed state. For example, a transition from “off” to “on” provides an active time period for pulse generation as does the transition from “off” to “on”. If it is desirable to produce pulses in only one transition time, the output of the cell may be forced into a steady state by providing a signal from the SCU through optional DAC 20(g) to switching element 30 interrupting the flow of current through Current Source 40. Alternatively, the data inputs at DPT 1 can be set to zero volts. A still further method of shutting down the cell would involve the SCU providing a signal through DAC 20(d) causing optional DPT 2 to turn off, thus isolating the input data signals at DPT 1 from the output terminals of the cell.

The electromagnetic pulse generation cell of FIG. 3 has three states of operation. In the first state, Control is at a voltage level higher than V3 plus the voltage drop across DPT 5 when on. In this state, DPT 5 is in the “on” state. Since the drain terminals (D) of DPT 5 are connected to Vdd, this DPT in the “on” state will create a lower voltage in DPTs source terminals (S). Since the voltage of Control minus the voltage drop across DPT 5 is still greater than voltage level V3, DPT 4 is still in the “off” state. With no current flowing through DPT 4, the voltage at the output terminals of the pulse generation cell will be Vdd.

In the third state of operation the voltage level of Control is lower than voltage level V2, which causes DPT 6 to be “on”. Since the source terminals (S) of DPT 6 are connected to the source terminals (S) of DPT 3, DPT 3 will have a higher voltage level at its source terminals (S) than at its gate terminals (G) and be in an “off” state. Like the first state, current flow across the resistive elements R1, R2 is interrupted and the output voltage will be approximately Vdd.

In the transition between the first and third states the pulse generation cell becomes active. When the control voltage is at an active switching level, DPT's 4, 5, 6, and 7 begin to transition from either an “on” state to an “off” state or from an “off” state to an “on” state. During this transition time period DPT 3 and DPT 4 allow current to flow across resistive elements R1, R2. The current flow causes a voltage drop from Vdd to be present at the differential output terminals. Since the amount of current through DPT 1 is dependent on the voltage level at the gate terminals (G) of DPT 1, the output signal will be proportional to the voltage level provided by the SCU through optional DACs 20(e) and 20(f). In this manner, electromagnetic pulse amplitude variation is software controllable by the SCU.

As the Control voltage reaches a deactivation switching point between V2 and V3, the circuit enters state 3, and the output terminals return to a steady state of approximately Vdd. Additionally, the amount of time that it takes Control to transition from the first switching point to the second is dependant on the specific voltage levels. The time duration of the active region can be controlled by setting V2 and V3 at different levels. Therefore, electromagnetic pulse width, or duration is also software controllable by the SCU.

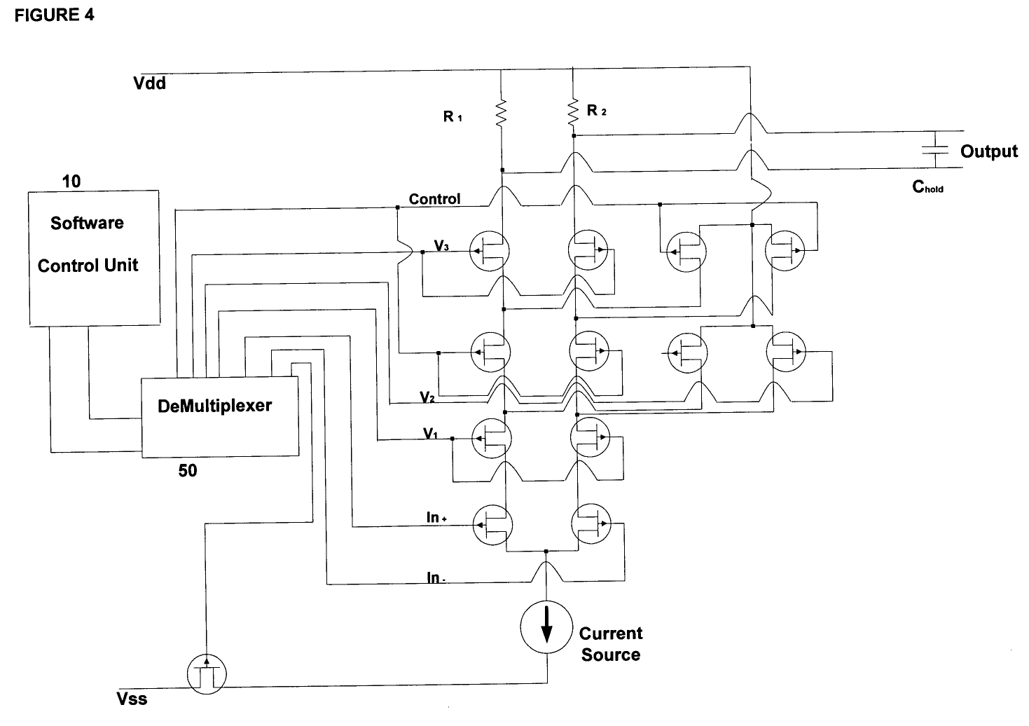

Referring now to FIG. 4, an alternative embodiment electromagnetic pulse generation cell, similar to the cell of FIG. 3 is illustrated. The pulse generation cell of FIG. 4 includes a demultiplexer. Another embodiment of an electromagnetic pulse generation cell may be configured as illustrated in FIG. 4, but may also include the DAC circuits 20(a-g) illustrated in FIG. 3. The embodiment illustrated in FIG. 4 is essentially constructed as illustrated and described above in connection with FIG. 3, with the exception that all signals from the SCU are sent to demultiplexer 50. Demultiplexer 50 is under the control of SCU 10. Control and data signals are sent to demultiplexer 50 from SCU 10. In this embodiment, the demultiplexer 50 routs the appropriate signals to the different parts of the pulse generation circuit illustrated in FIG. 4.

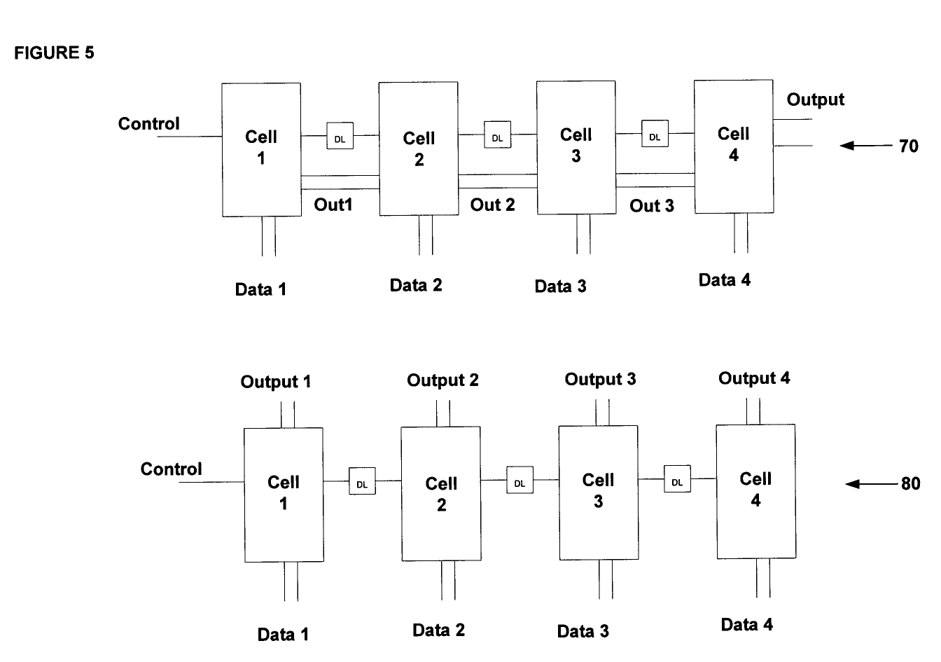

Referring to FIG. 5, two configurations of pulse generation cells constructed according to the present invention are illustrated. Each of cells 1-4 represents any one of the pulse generation cells illustrated in FIGS. 3 and 4, or alternative embodiments thereof. It will be appreciated that any number of pulse generation cells may be employed by the present invention, with the four cells illustrated for drawing expediency. Cell array 70 is a Serial Array Single Output (SASO). In this configuration, data 1-4 is input into each cell 1-4, and the control inputs are serially connected in cell array 70 with the use of delay lines (DL). Cell array 70 is configured to give a single differential output. Alternatively, cell array 80 is a Serial Array Multiple Output array (SAMO). This configuration is serially connected with respect to the control signal, with data 1-4 input into each cell 1-4, but each cell has an independent output 1-4.

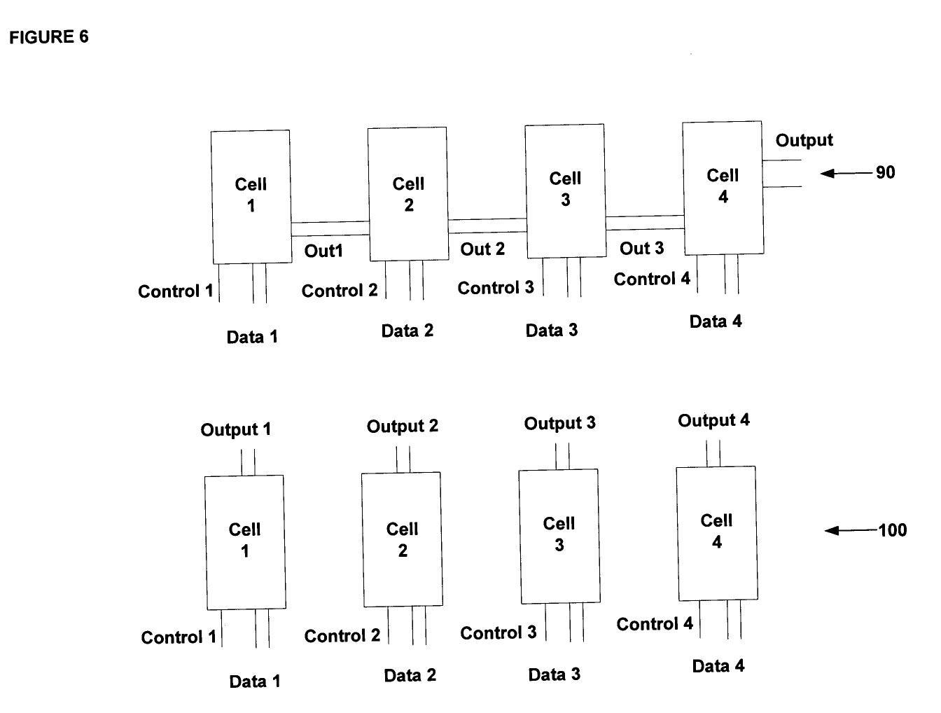

Referring to FIG. 6, two additional configurations of pulse generation cells constructed according to the present invention are illustrated. Each of cell 1-4 represents any one of the pulse generation cells illustrated in FIGS. 3 and 4, or alternative embodiments thereof. It will be appreciated that any number of pulse generation cells may be employed by the present invention, with the four cells illustrated for drawing expediency. Cell array 90 is a Parallel Array Single Output (PASO). In this configuration, data 1-4 is input into each cell 1-4, and the control inputs 1-4 are individually input into each cell 1-4. The entire cell array 90 is configured to give a single differential output. Alternatively, cell array 100 is a Parallel Array Multiple Output array (PAMO). In this configuration, the control inputs 1-4 are individually input into each cell 1-4, but each cell has an independent output 1-4.

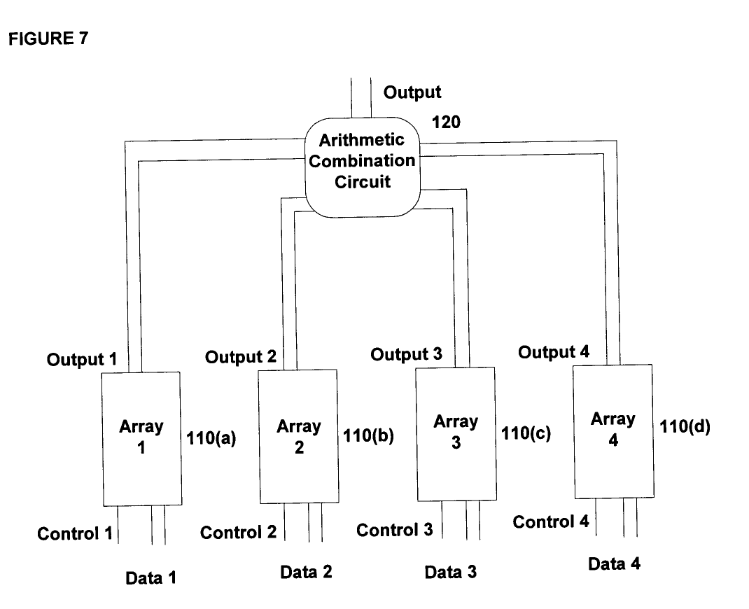

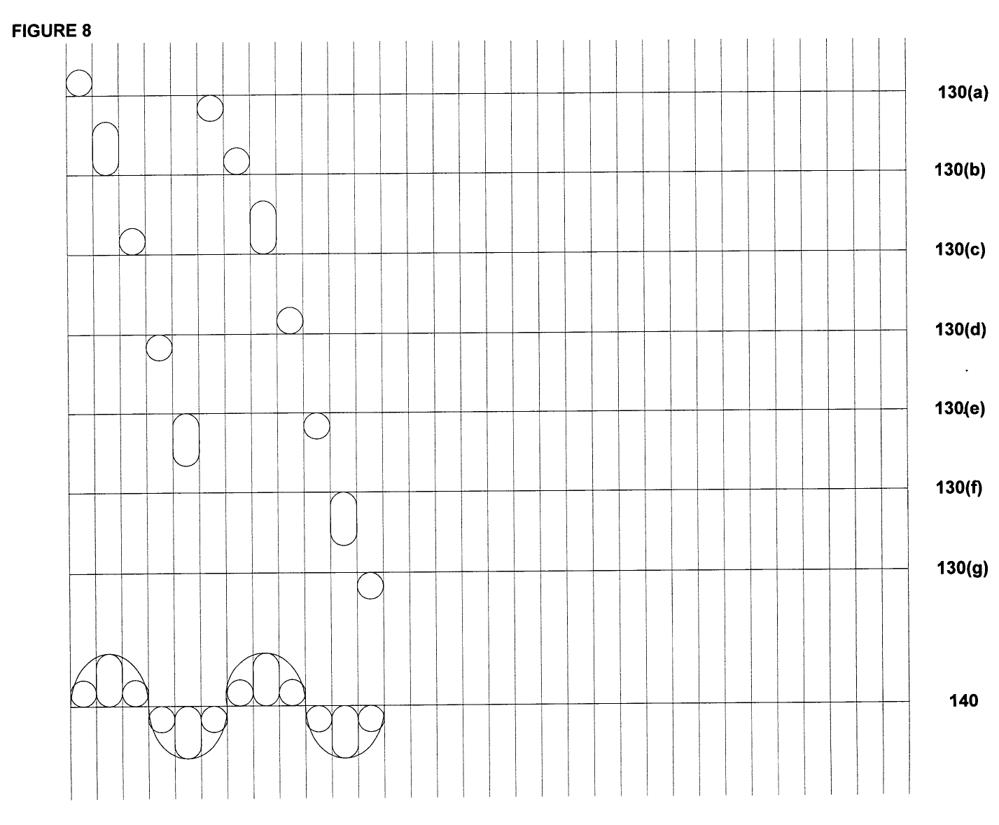

Referring to FIG. 7, an arithmetic combination circuit 120 is combined with a group of array elements 1-4. The output from the arithmetic combination circuit 120 may be used to produce any desired electromagnetic waveform. It will be appreciated that any number of array elements may be employed by the present invention, with the four array elements illustrated for drawing expediency. Array elements 110(a-d) are connected in parallel to Arithmetic Combination Circuit 120. The Array elements shown may comprise the cell arrays 70, 80, 90 and 100 (SASO, SAMO, PASO, and PAMO) as described above in connection with FIGS. 5-6. Any number of array elements may be used to produce a desired electromagnetic waveform. Data 1-4 is input into the array elements 1-4, and the outputs 1-4 of the array elements 110(a-d) are connected to arithmetic combination circuit 120. The arithmetic combination circuit 120 may comprise switching elements, summing circuits, inverting circuits, integrating and differentiating circuits, mixers, multipliers, and other suitable devices. Additionally, the arithmetic combination circuit 120 may be computer software controllable, and may or may not include DAC circuitry.

FIG. 8 illustrates a sinusoidal waveform generated by the arithmetic aggregation of outputs from the cells 1-4 or arrays 1-4. In this example, the cell 1-4 or array 1-4 outputs 130(a-g) are summed to produce a sinusoidal waveform as an output 140. Each output 130(a-g), corresponding to the outputs from the cells 1-4 or arrays 1-4, is independently controllable, as discussed above in connection with the operation of the cells 1-4 and array elements 1-4. Thus, any desired waveform, having any desired frequency, amplitude, or other characteristic, such as waveform 140, shown in FIG. 8, can be produced by the arithmetic combination circuit 120.

One feature of the present invention is that data modulation may be performed simultaneously with pulse generation, with the generated pulses or aggregated waveform reflecting the modulated data.

That is, conventional carrier wave, or sinusoidal wave communication technologies, like cellular communication systems, must first produce a sinusoidal wave signal at the appropriate frequency and then vary the signal so that it can carry data. Varying the signal is known as modulation, which is a method of varying a carrier frequency so that a signal can ride on it. Put differently, two signals are combined, with the result that one signal is varied by the other. The varied signal is then transmitted, received, and then de-modulated to recover the data.

One feature of the present invention is that the modulation step is performed substantially simultaneously with the generation of electromagnetic pulses, greatly simplifying the communication process. For example, as shown in FIG. 8, individual pulses 103 (a-g) are generated by the cells 1-4 and/or arrays 1-4 described above. The pulses are summed to produce a sinusoidal waveform 140. In a conventional communication system, the waveform would then be varied by the modulated data signal. However, the present invention can directly produce a sinusoidal waveform 140 that already includes the modulated data. Thus, the waveform 140, generated in a single aggregation step, would include the desired data, and would be transmitted without any modulation step(s).

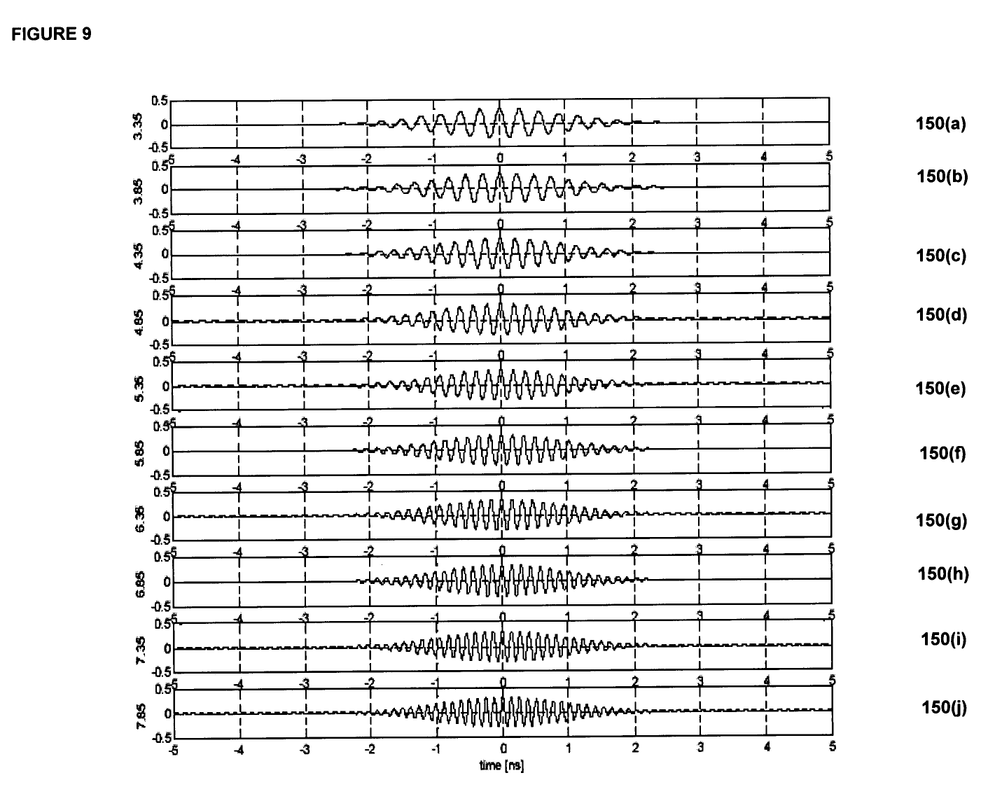

FIGS. 9 and 10 illustrate electromagnetic pulses, and their associated frequency spectra, generated by the outputs from one or more cells 1-4 or arrays 1-4. In this example, the cell 1-4 or array 1-4 outputs are in the form of a plurality of pulses 1 50(a-j), shown in FIG. 9. Shown in FIG. 10, are the frequency spectra 160(a-j) corresponding to each of the pulses 150(a-j). As illustrated, higher-oscillation pulses have a higher frequency.

One feature of the present invention is that pulses 150 (a-j) having frequency spectra 160 (a-j) may be used in a multi-band ultra-wideband (UWB) communication system. For example, multi-band UWB systems usually fall into two architectures. The first architecture generates a electromagnetic pulse with a duration relating to the amount of frequency to be occupied by the band. The UWB pulse is then filtered with a bandpass filter that has a center frequency at the center of the frequency band to be occupied. When transmitted, the resultant pulse will occupy the appropriate amount of frequency around the center of the bandpass filters bandwidth.

A second multi-band UWB communication architecture involves generating a pulse with the appropriate bandwidth and mixing it with a carrier wave of the desired center frequency. The complexity of both architectures is significant.

In one embodiment of the present invention, multi-band UWB pulses are generated directly without the use of mixing circuits and bandpass filters. These pulse streams are generated directly, or are generated by the aggregation of pulse generation cells using the arithmetic combination circuit 120, shown in FIG. 7. Since the electromagnetic pulse generator herein described is controlled by computer software, it has the ability to quickly and easily switch between single-band UWB communication architectures and multi-band UWB communication architectures by generating pulses with characteristics suitable to each architecture. Additionally, the same electromagnetic pulse generator may be used to generate a wide range of conventional sine wave, or carrier wave signals, as shown in FIG. 8.

In addition, an electromagnetic pulse generator constructed according to the present invention may generate pulses that avoid specific frequencies, such as the GPS band that extends from 0.96 to 1.61 GHz, or any other frequencies of interest. In this fashion, an ultra-wideband communication system may be “tuned” to avoid specific frequencies, without the use of band-pass filters or other devices.

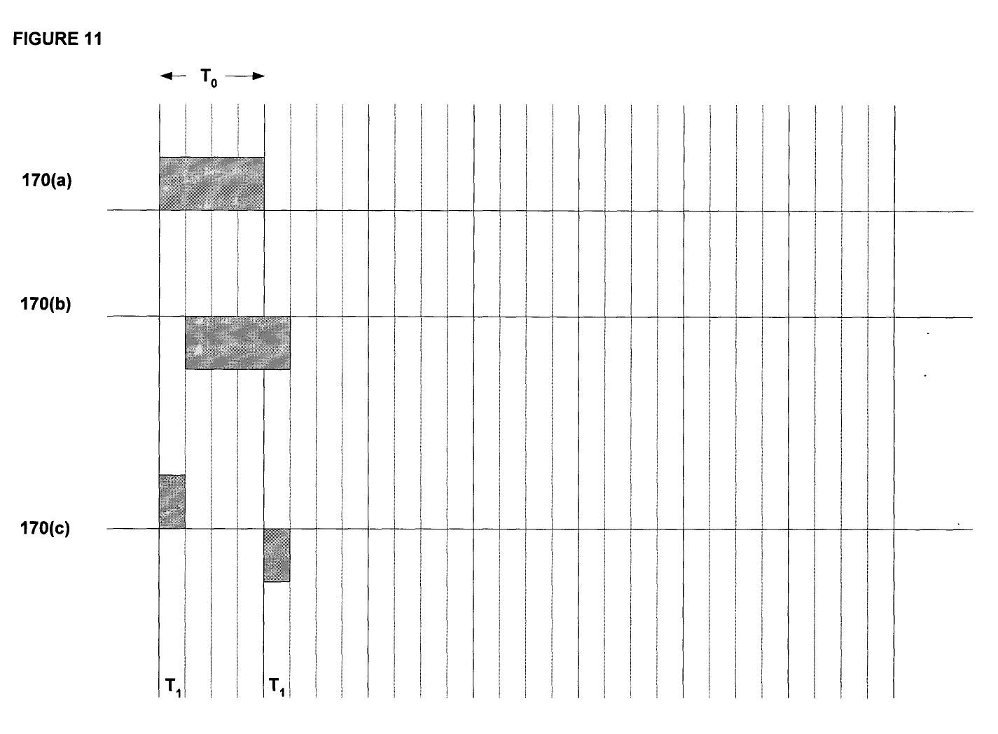

Referring to FIG. 11, in another embodiment of the present invention, extremely short duration electromagnetic pulse durations can be obtained by initially generating pulses 170(a) and 170(b). These pulses may be used as described above, in an ultra-wideband communication system. The initial pulses 170(a) and 170(b) may have duration T₀. The arithmetic combination circuit 120 (shown in FIG. 7) is used to narrow the resulting pulses to duration T₁ by delaying pulse 170(b) by amount T₁, and performing an arithmetic function (addition in the case shown) on the two pulses. The resultant pulses 170(c) have duration T₁. For example, the extremely short electromagnetic pulse generation cells and/or arrays herein described are capable of generating pulses with durations of 50 picoseconds or less. With the use of delay lines, pulse 170(b) can be delayed by 10 picoseconds relative to pulse 170(a). The sum of pulses 170(a) and 170(b) shown in 170(c) would then have a duration of 10 picoseconds. By adjusting the delay lines, electromagnetic pulse durations of 1 picosecond are attainable. Pulses 170(c) may be employed individually, or aggregated for use in an ultra-wideband communication system, with discrete pulses ranging from about 1 pico-second to about 1 milli-second in duration.

And, as discussed above, modulation of the ultra-wideband pulses may be performed before pulse generation, eliminating the modulation step, thereby simplifying the communication system. That is, the present invention can directly produce electromagnetic pulses for use in an ultra-wideband communication system that already include the modulated data. Thus, the pulses would include the desired data when produced, and would be transmitted without any modulation step(s).

Thus, it is seen that systems, methods and articles of manufacture are provided for electromagnetic pulse generation suitable for communications in a wired or wireless medium. One skilled in the art will appreciate that the present invention can be practiced by other than the above-described embodiments, which are presented in this description for purposes of illustration and not of limitation. The description and examples set forth in this specification and associated drawings only set forth preferred embodiment(s) of the present invention. The specification and drawings are not intended to limit the exclusionary scope of this patent document. Many designs other than the above-described embodiments will fall within the literal and/or legal scope of the following claims, and the present invention is limited only by the claims that follow. It is noted that various equivalents for the particular embodiments discussed in this description may practice the invention as well.

1. An electromagnetic pulse generator comprising:
a control unit;
a first input stage having a data input terminal; and
a plurality of switching elements coupled to the input stage, the switching elements responsive to a first voltage level and a second voltage level;
wherein the control unit provides a transition signal from the first voltage level to the second voltage level.

2. The electromagnetic pulse generator of claim 1, wherein the control unit is selected from a group consisting of: a digital computer, and a digital to analog converter including computer logic for controlling the digital to analog converter.

3. The electromagnetic pulse generator of claim 1, wherein the first input stage comprises a differential pair.

4. The electromagnetic pulse generator of claim 1, wherein the first voltage level is greater than the second voltage level.

5. The electromagnetic pulse generator of claim 1, wherein the transition signal from the first voltage level to the second voltage level is provided by the control unit.

6. The electromagnetic pulse generator of claim 1, wherein the switching elements are selected from a group consisting of: differentially paired transistors and differentially paired diodes.

7. The electromagnetic pulse generator of claim 1, wherein the electromagnetic pulses may vary in amplitude from about −5 volts to about 5 volts.

8. The electromagnetic pulse generator of claim 1, wherein the electromagnetic pulses may have a duration from about 1 pico-second to about 1 milli-second.

9. The electromagnetic pulse generator of claim 1, wherein the plurality of electromagnetic pulses represent data.

10. The electromagnetic pulse generator of claim 1, wherein the plurality of electromagnetic pulses are employed in an ultra-wideband communication system.

11. The electromagnetic pulse generator of claim 1, wherein a plurality of electromagnetic pulses produced by the electromagnetic pulse generator are aggregated to form a sinusoidal waveform.

12. The electromagnetic pulse generator of claim 11, wherein the sinusoidal waveform is employed to transmit data.

13. An electromagnetic pulse generating circuit comprising:
a differential pair having at least two gate terminals coupled to at least two input terminals;
at least two switching elements coupled to the differential pair, the switching elements responsive to a first voltage level and a second voltage level;
at least two digital to analog converters configured to selectively provide a positive and a negative activation signal to the switching elements; and
a digital computer communicating with the digital to analog converters to control the positive and negative activation signals.

14. The electromagnetic pulse generating circuit of claim 13, wherein a transition of the positive activation signal from a first voltage level to a second voltage level generates an electromagnetic pulse when the positive activation signal is between a first switching point and a second switching point.

15. The electromagnetic pulse generating circuit of claim 14, wherein the first voltage level is greater than the second voltage level.

16. The electromagnetic pulse generating circuit of claim 13, wherein a transition of the negative activation signal from a first voltage level to a second voltage level generates an electromagnetic pulse when the negative activation signal is between a first switching point and a second switching point.

17. The electromagnetic pulse generating circuit of claim 16, wherein the first voltage level is greater than the second voltage level.

18. The electromagnetic pulse generating circuit of claim 13, wherein the switching elements comprise at least two transistors.

19. The electromagnetic pulse generating circuit of claim 13, wherein the switching elements comprise at least two diodes.

20. An electromagnetic pulse generating circuit comprising:
a first pair of differentially paired transistors having at least two gate terminals connected to at least two input terminals, at least two drain terminals, and at least two source terminals connected to a current source;
a second pair of differentially paired transistors having at least two gate terminals coupled to a first voltage level, with at least two source terminals coupled to the drain terminals of the first pair of transistors;
a third pair of differentially paired transistors having at least two gate terminals connected to a digital to analog converter, with at least two source terminals coupled to the drain terminals of the second pair of transistors;
a digital computer connected to the digital to analog converter;
a fourth pair of differentially paired transistors having gate terminals connected to a third voltage level, with at least two source terminals coupled to the drain terminals of the third pair of transistors, and at least two drain terminals connected to a differential output; and
a first resistive element and a second resistive element each having a first terminal connected to a power supply and a second terminal connected to the drain terminals of the fourth pair of differentially connected transistors.

21. The electromagnetic pulse generating circuit of claim 20, wherein the second, third, and fourth pairs of differentially paired transistors comprise switching elements responsive to the first voltage level, the third voltage level and the output of the digital to analog converter.

22. The electromagnetic pulse generating circuit of claim 20, wherein the digital to analog converter is controlled by computer logic stored in the digital computer.

23. The electromagnetic pulse generating circuit of claim 20, wherein the first, second, third and fourth differentially paired transistors are activated by the digital to analog converter to generate an electromagnetic pulse when the output of the digital to analog converter is greater than the first voltage but less than the third voltage.

24. The electromagnetic pulse generating circuit of claim 20, further comprising:
a capacitor connected to the differential output.

25. The electromagnetic pulse generating circuit of claim 20, further comprising:
a fifth pair of differentially paired transistors having at least two gate terminals connected to the digital to analog converter, and a source terminal connected to at least two drain terminals of the third pair of differentially connected transistors and to the source terminals of the fourth pair of differentially paired transistors.

26. The electromagnetic pulse generating circuit of claim 20, further comprising:
a sixth pair of differentially paired transistors having at least two gate terminals connected to a second voltage level, and at least two source terminals connected to the drain terminals of the second pair of differentially connected transistors, and a drain terminal connected to the power supply.

27. The electromagnetic pulse generating circuit of claim 20, further comprising:
a demultiplexer connected to each of the differentially paired transistors without a digital to analog converter, and to the digital computer.

28. The electromagnetic pulse generating circuit of claim 20, wherein the differentially paired transistors are selected from a group consisting of: a gallium arsenide (GaAs) transistor, a MESFET transistor, a GaAs hetrojunction bipolar transistor (HBT), a GaAs high electron mobility transistor (HEMT), an indium phosphate transistor, a silicon germanium transistor, a silicon bipolar transistor, and a MOS transistor.

29. An electromagnetic pulse generating system comprising:
control means for generating a plurality of digital signals;
demultiplexing means for demultiplexing the plurality of digital signals;
electromagnetic pulse generating means for generating a plurality of electromagnetic pulses in response to the plurality of digital signals; and
aggregating means for combining the plurality of electromagnetic pulses.

30. The electromagnetic pulse generating system of claim 29, wherein the aggregating means combines the plurality of electromagnetic pulses into a desired sinusoidal waveform or into a group of electromagnetic pulses.

31. The electromagnetic pulse generating system of claim 29, wherein the plurality of electromagnetic pulses are generated in response to a voltage transition in a one the plurality of digital signals.

32. The electromagnetic pulse generating system of claim 29, wherein the control means comprises a digital computer microprocessor controlled by computer logic.

33. The electromagnetic pulse generating system of claim 29, wherein the control means comprises a finite state machine.

34. The electromagnetic pulse generating system of claim 29, wherein the electromagnetic pulse generating means comprises:
a digital to analog conversion circuit, configured to receive the digital signal from the demultiplexing means; and
a plurality of connected pulse generation circuits, wherein each pulse generation circuit is responsive to a voltage transition of an output from the digital to analog conversion circuit.

35. The electromagnetic pulse generating system of claim 29, wherein the electromagnetic pulse generating means are connected in parallel.

36. The electromagnetic pulse generating system of claim 29, wherein the electromagnetic pulse generating means are connected in series.

37. The electromagnetic pulse generating system of claim 29, wherein the aggregating means comprises a summing circuit.

38. The electromagnetic pulse generating system of claim 29, wherein the aggregating means includes a multiplier.

39. A method of generating an electromagnetic pulse, the method comprising the steps of:
providing a digital computer containing computer logic;
transitioning an output of a digital to analog conversion circuit from a first voltage level to a second voltage level;
generating a first electromagnetic pulse in response to the voltage transition; and
generating a second electromagnetic pulse in response to a second voltage transition.

40. The method of generating the electromagnetic pulse of claim 39, wherein the step of generating the second electromagnetic pulse in response to the second voltage transition comprises:
generating the second electromagnetic pulse when an output of the digital to analog conversion circuit transitions from the second voltage level to the first voltage level.

41. The method of generating the electromagnetic pulse of claim 39, further comprising the step of:
maintaining a steady state when a voltage level of the digital to analog conversion circuit is outside a voltage range of the first voltage level and the second voltage level.

42. The method of generating the electromagnetic pulse of claim 39, wherein the first electromagnetic pulse is generated when the output from the digital to analog conversion circuit reaches a first switching point and ceases when the output of the digital to analog conversion circuit reaches a second switching point, the first and second switching points occurring between the first and second voltage levels.

43. The method of generating the electromagnetic pulse of claim 39, wherein the second electromagnetic pulse is generated when the output of the digital to analog conversion circuit reaches a second switching point and ceases when the output of the digital to analog conversion circuit reaches a first switching point, the first and second switching points occurring between the first and second voltage levels.

44. A method of generating an output signal in a computer circuit, the method comprising the steps of:
providing a digital computer;
generating the output signal having two transitions in response to a single transition of a control signal sent by the digital computer;
wherein a first transition of the two transitions is a rise of the output signal from an initial voltage to a second voltage; and
wherein a second transition of the two transitions is a fall of the output signal to the initial operating voltage.

45. The method of generating an output signal in a computer circuit of claim 44, wherein the computer circuit includes at least two differentiating circuit elements comprising capacitors.

46. The method of generating an output signal in a computer circuit of claim 44, wherein the digital computer comprises a digital to analog conversion circuit.

47. The method of generating an output signal in a computer circuit of claim 44, wherein the computer circuit includes a signal reversing element comprising a transmission line or a delay line.

48. A method of generating an output signal in a computer circuit, the method comprising the steps of:
providing a digital computer;
sending a control signal from the digital computer, the control signal including a voltage transition;
conveying to one or more computer circuit output terminals a voltage proportional to the voltage on one or more respective input terminals; and
wherein the voltage conveyed to the one or more output terminals is proportional to the voltage on the one or more input terminals during a time when the voltage transition occurs in the control signal.

49. The method of generating an output signal in a computer circuit of claim 48, wherein the computer circuit includes at least two differentiating circuit elements comprising capacitors.

50. The method of generating an output signal in a computer circuit of claim 48, wherein the digital computer comprises a digital to analog conversion circuit.

51. The method of generating an output signal in a computer circuit of claim 48, wherein the computer circuit includes a signal reversing element comprising a transmission line or a delay line.

52. The method of generating an output signal in a computer circuit of claim 48, further comprising the step of:
holding the voltage on the one or more output terminals after the transition of the control signal.

53. The method of generating an output signal in a computer circuit of claim 52, wherein, the holding is provided by an electric storage comprising a capacitor.

54. A method of transmitting data, the method comprising the steps of:
receiving data for transmission;
modulating the data;
providing an electromagnetic pulse generating circuit;
generating a plurality of electromagnetic pulses arranged to represent the modulated data; and
transmitting the plurality of electromagnetic pulses.

55. The method of transmitting data of claim 54, wherein the step of generating a plurality of electromagnetic pulses comprises means for generating a plurality of electromagnetic pulses.
